(19) United States
(12) Patent Application Publication
(10) Pub. No.: US 2026/0244584 A1
(43) Pub. Date: Aug. 20, 2026

(54) MEMORY PACKAGE, PROCESSOR PACKAGE, AND COMPUTING SYSTEM

(71) Applicant: SK hynix Inc., Icheon-si (KR)

(72) Inventor: Dong Sop LEE, Icheon-si (KR)

(21) Appl. No.: 19/400,776

(22) Filed: Nov. 25, 2025

(30) Foreign Application Priority Data
Feb. 17, 2025 (KR) 10-2025-0020281
Sep. 17, 2025 (KR) 10-2025-0133932

(51) Int. Cl. G06F 13/16

(52) U.S. Cl. CPC G06F 13/1668

(57) ABSTRACT

Disclosed is a structure integrating a processing unit performing a training operation for learning an artificial intelligence model, a memory device used to store parameter data according to the training operation, and a storage device for backing up checkpoint data generated based on the parameter data, thereby providing a method for improving performance degradation due to generation and storage of checkpoint data through direct movement of checkpoint data between the memory device and the storage device.

### CROSS-REFERENCE TO RELATED APPLICATIONS

The present application claims priority under 35 U.S.C. 119(a) to Korean patent application number 10-2025-0020281 filed on February 17, 2025, and Korean patent application number 10-2025-0133932 filed on September 17, 2025, which are incorporated herein by reference in their entireties.

### TECHNICAL FIELD

The embodiments of the present disclosure relate to a memory package, a processor package, and a computing system.

### BACKGROUND

A computing system may include a processor that performs calculations or operations. The computing system may include memory for storing data used by the processor when performing operations. The memory included in the computing system may be volatile or non-volatile memory, and in some cases, heterogeneous memory may be included in the computing system.

The computing system may perform training operations for learning an artificial intelligence model or inference operations using an artificial intelligence model. As the computing system performs operations related to the artificial intelligence model, the amount of data transferred between the processor and memory during performance of operation processes may increase. Therefore, a method is needed for efficiently controlling data transfer to improve the performance of the computing system.

### SUMMARY

The tasks of the embodiments of the present disclosure are not limited to the tasks mentioned in this disclosure, and other tasks not mentioned will be clearly understood by those skilled in the art from the description below.

Embodiments of the disclosure may provide a structure of a computing system and an operating method capable of efficiently controlling the movement of data between a processor and a memory during the process of performing operations related to artificial intelligence models.

Embodiments of the present disclosure may provide a computing system including a processing unit, at least one memory device, including a first interface circuit configured to communicate with the processing unit and a first chip-to-chip interface circuit, and configured to store parameter data generated by an operation performed by the processing unit, and at least one storage device including a second chip-to-chip interface circuit configured to communicate with the at least one memory device, and configured to receive and store at least a portion of checkpoint data generated at a preset time based on the parameter data from the at least one memory device.

Embodiments of the present disclosure may provide a memory package including a package substrate, at least one first memory device disposed on the package substrate, including a base die and at least one first memory disposed on the base die, the base die including a first interface circuit configured to communicate with an externally located processing unit and a first chip-to-chip interface circuit, and at least one second memory device disposed on the package substrate, including at least one second memory and a controller controlling the at least one second memory, the controller including a second interface circuit configured to communicate with the at least one second memory and a second chip-to-chip interface circuit configured to communicate with the at least one first memory device.

Embodiments of the present disclosure may provide a processor package including a package substrate, a processing unit on the package substrate, and at least one memory device including an interface circuit configured to communicate with the processing unit and a chip-to-chip interface circuit, storing parameter data generated by an operation performed by the processing unit, and configured to transmit at least a portion of checkpoint data generated based on the parameter data to an outside through the chip-to-chip interface circuit.

According to embodiments of the present disclosure, it is possible to improve the operating performance of a computing system performing operations related to an artificial intelligence model by efficiently controlling the movement of data generated when performing operations related to the artificial intelligence model.

The effects of the embodiments of the present disclosure are not limited to the described effects, and other effects not mentioned will be clearly understood by those skilled in the art from the description of the claims.

### BRIEF DESCRIPTION OF THE DRAWINGS

The present disclosure will be more fully understood from the detailed description and accompanying drawings provided below, which are provided for illustration purposes only and are not intended to limit the present disclosure.

FIG. 1 illustrates an example of a schematic configuration of a computing system according to embodiments of the present disclosure.

FIG. 2 illustrates an example of a structure of a computing system according to embodiments of the present disclosure.

FIG. 3 illustrates an example of a schematic configuration of a memory device and a storage device according to embodiments of the present disclosure.

FIGS. 4 and FIG. 5 illustrate examples of a method of operating a computing system to perform operations related to an artificial intelligence model according to embodiments of the present disclosure.

FIGS. 6A, FIG. 6B, FIG. 7, FIG. 8A, and FIG. 8B illustrate other examples of specific structures of computing systems according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element may be included in at least one of two or more elements that "are connected or coupled to", “contact or overlap”, etc. each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

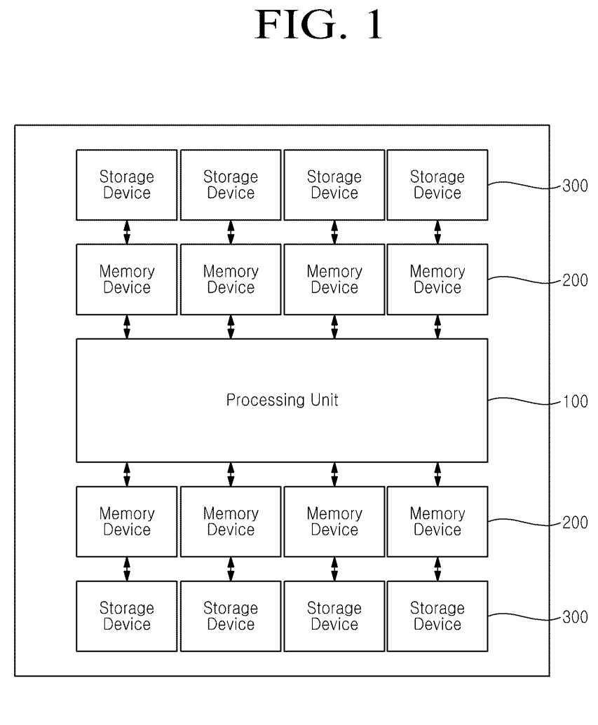

FIG. 1 illustrates an example of a schematic configuration of a computing system according to embodiments of the present disclosure.

Referring to FIG. 1, a computing system may include at least one processing unit 100. The processing unit 100 may perform operations or calculations using various types of data. For example, the processing unit 100 may perform a training operation for learning an artificial intelligence model, or may perform an inference operation using an artificial intelligence model.

The processing unit 100 may be, for example, a graphics processing unit (GPU), but embodiments are not limited thereto. In some cases, the processing unit 100 may be one of various processors that provide calculation functions, such as a neural network processing unit (NPU), a tensor processing unit (TPU), or a central processing unit (CPU). The computing system may further include a host device, and the processing unit 100 may perform an operation at the request of the host device.

The host device may be, for example, a computer, an ultra mobile PC (UMPC), a workstation, a personal digital assistant (PDA), a tablet, a mobile phone, a smart phone, an e-book, a portable multimedia player (PMP), a portable game console, a navigation device, a black box, a digital camera, a digital multimedia broadcasting (DMB) player, a smart television, a digital voice recorder, a digital voice player, a digital image recorder, a digital image viewer, a digital video recorder, a digital video player, storage constituting a data center, one of various electronic devices constituting a home network, one of various electronic devices constituting a telematics network, an radio frequency identification (RFID) device, a mobile device (e.g., a vehicle, a robot, a drone) that can drive under human control or autonomously, etc. Alternatively, the host device may be a virtual/augmented reality device that provides two-dimensional or three-dimensional virtual reality images or augmented reality images. In addition to the examples described above, the host device may be any of various electronic devices that include a processing unit 100 or require the use of a data storage device. The operation of the processing unit 100 may be controlled by the host device.

The computing system may include at least one data storage device for storing data used when performing operations by the processing unit 100. For example, the computing system may include at least one memory device 200. In addition, the computing system may include at least one storage device 300.

The memory device 200 may be, for example, a volatile memory. The storage device 300 may be, for example, a non-volatile memory, but embodiments are not limited thereto. The memory device 200 and the storage device 300 may be different types of data storage devices or may be the same type of data storage devices. At least one of the memory device 200 and the storage device 300 may further include a computational circuit that provides a computational function. In addition to the function of storing data by the memory device 200 or the storage device 300, a computational function may be provided by the computational circuit. At least a portion of the operations performed by the processing unit 100 may also be performed by the memory device 200 or the storage device 300. In this disclosure, the memory device 200 may be referred to as a first memory device, and the storage device 300 may be referred to as a second memory device.

The processing unit 100 may communicate with the memory device 200. The memory device 200 may communicate with the storage device 300. The processing unit 100 may communicate with the storage device 300 via the memory device 200. In some cases, the processing unit 100 may also communicate directly with the storage device 300.

The processing unit 100 may store data used when performing an operation using the memory device 200. The processing unit 100 may store data in the memory device 200, perform an operation using the data stored in the memory device 200, and store data according to the result of the operation in the memory device 200.

The processing unit 100 may store at least a portion of the data generated as a result of performing an operation in the storage device 300. For example, the processing unit 100 may store the data, which is stored in the memory device 200, in the storage device 300 in order to back up the data. Alternatively, the processing unit 100 may manage the data stored in the memory device 200 and the data stored in the storage device 300 separately. The processing unit 100 may store the data in the memory device 200 or the storage device 300 depending on the properties of the data.

The processing unit 100 and the memory device 200 may communicate with each other, and the memory device 200 and the storage device 300 may communicate with each other. As a result, the processing unit 100 may perform operations using the memory device 200 and store data using the storage device 300. For example, the processing unit 100 may generate parameters by performing calculations using data stored in the memory device 200, and the processing unit 100 may store the parameters in the storage device 300. The processing unit 100 may store data in the storage device 300 for backing up the data or for using the data in next calculations.

The processing unit 100, the memory device 200, and the storage device 300 may be packaged and provided in various forms according to the communication structure as described above.

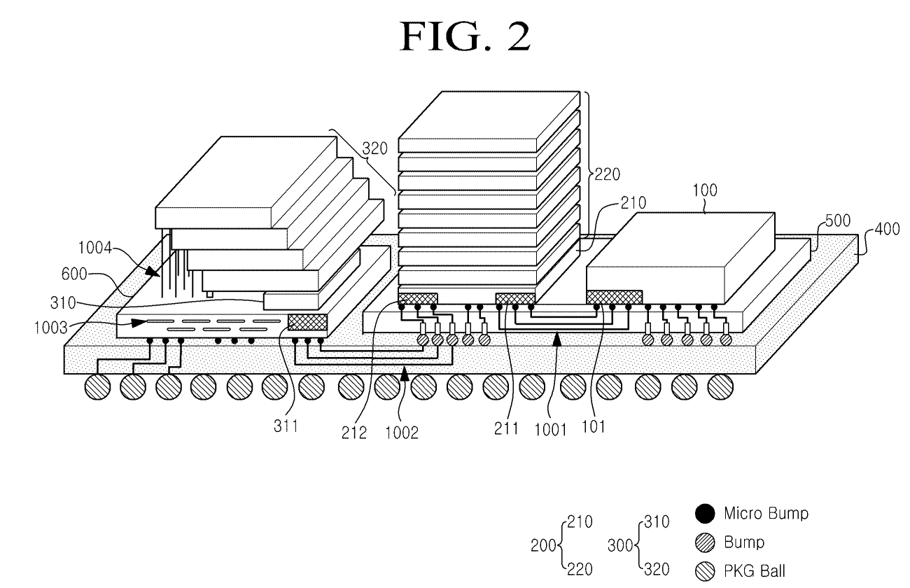

FIG. 2 illustrates an example of a structure of a computing system according to embodiments of the present disclosure.

FIG. 2 illustrates an example of the arrangement and connection structure of a processing unit 100, memory device 200, and storage device 300 included in a computing system.

The processing unit 100, the memory device 200, and the storage device 300 may be disposed on, for example, a package substrate 400. The package substrate 400 may be, for example, a printed circuit board, but embodiments are not limited thereto. At least one package ball (PKG ball) may be disposed on a lower surface of the package substrate 400. The package substrate 400 may be electrically connected to a device located outside the computing system through the package ball. For example, the processing unit 100 may be electrically connected to a host device through package balls, and a signal transmitted from the host device may be transmitted to the processing unit 100 or the storage device 300 through the package balls.

At least a portion of the processing unit 100, the memory device 200, and the storage device 300 located on the package substrate 400 may be disposed on a sub-package substrate. For example, the processing unit 100 and the memory device 200 may be disposed on an interposer 500. The interposer 500 may be, for example, a substrate made of silicon, but embodiments are not limited thereto. The interposer 500, including the processing unit 100 and the memory device 200, may be referred to as a processor package.

At least one bump may be arranged on a lower surface of the interposer 500. A bump may be electrically connected to a portion of the package ball. A signal received through a package ball may be provided to a processing unit 100 through a bump. A communication path to storage device 300 may be provided through the bump. A “path”, “communication path” and “path for communication” may all mean a structure through which data and signals can be transmitted.

At least one micro bump may be arranged on the lower surface of the processing unit 100 on the interposer 500. At least one micro bump may be arranged on the lower surface of the memory device 200 on the interposer 500. The processing unit 100 and the memory device 200 may be electrically connected to each other and communicate with each other through the micro bump. The interposer 500 may provide a communication path 1001 between the processing unit 100 and the memory device 200.

The processing unit 100 may include a processing interface circuit 101 for communicating with the memory device 200. The processing interface circuit 101 may include, for example, a network layer supporting Advanced eXtensible Interface (AXI), a data link layer supporting Ultra Chiplet Interconnect Express (UCIe), and a physical layer, and may support UCIe-based communication, but embodiments are not limited thereto.

The processing unit 100 may communicate with a first interface circuit 211 included in the memory device 200 through the processing interface circuit 101. The first interface circuit 211 may support the same type of communication protocol as the processing interface circuit 101.

The memory device 200 may be, for example, a high-bandwidth memory (HBM). The memory device 200 may include, for example, a base die 210 and at least one core die 220 on the base die 210. The base die 210 may include various circuits or connection wiring for the operation of the memory device 200.

The core die 220 may include memory cells capable of storing data. In some cases, a logic circuit may be disposed in a portion of the core die 220. FIG. 2 illustrates eight core dies 220, but the present disclosure is not limited thereto. In this disclosure, the core die 220 may also be referred to as a first memory.

The base die 210 may include the first interface circuit 211 and a first chip-to-chip interface circuit 212. The base die 210 may include a plurality of through-electrodes for communication with the core die 220. A signal received through the first interface circuit 211 may be transmitted to a core die 220 through the through-electrode. Data stored in the core die 220 may be provided to the processing unit 100 through the through-electrode and the first interface circuit 211.

The first chip-to-chip interface circuit 212 may be arranged to communicate with the storage device 300. The first chip-to-chip interface circuit 212 may include, for example, a network layer supporting AXI, a data link layer supporting UCIe, and a physical layer, and may support UCIe-based communication, but embodiments are not limited thereto. The first chip-to-chip interface circuit 212 may be electrically connected to the interposer 500 through micro bumps. The first chip-to-chip interface circuit 212 may communicate with the storage device 300 via a communication path provided by the bumps arranged on the lower surface of the interposer 500 and on the package substrate 400. A communication path between the memory device 200 and the storage device 300 is indicated in FIG. 2 by 1002.

The storage device 300 may be disposed on a redistribution layer 600, which is arranged on the package substrate 400. In some cases, the storage device 300 may be include the redistribution layer 600.

The storage device 300 may include a controller 310 and at least one memory 320. The at least one memory 320 may be, for example, a non-volatile memory. The memory 320 included in the storage device 300 may also be referred to as a second memory in this disclosure.

The controller 310 may control the operation of the memory 320. The controller 310 may include a second chip-to-chip interface circuit 311 for communicating with the memory device 200. At least a portion of the second chip-to-chip interface circuit 311 may, in some cases, be located on the redistribution layer 600. The second chip-to-chip interface circuit 311 may be located on the redistribution layer 600 and the controller 310.

The controller 310 and the memory 320 may be connected and communicate with each other through a signal wiring. The arrangement structure and the communication structure of the controller 310 and the memory 320 may be implemented in various ways.

For example, the controller 310 may be disposed on the redistribution layer 600. At least one memory 320 may be disposed on the controller 310. FIG. 2 illustrates an example in which four memories 320 are arranged on the controller 310, but embodiments are not limited thereto.

The controller 310 and the memory 320 may communicate with each other via signal wirings provided by the redistribution layer 600. For example, as indicated by 1003, a communication path between the controller 310 and the memory 320 may be provided by the redistribution layer 600. The memory 320 may be electrically connected to the redistribution layer 600 via at least one vertical connection wiring arranged on the redistribution layer 600, as indicated by 1004. The memory 320 may be connected to the redistribution layer 600 via the vertical connection wiring, may receive various control signals from the controller 310, and may provide data to the controller 310.

In a structure where a processing unit 100, a memory device 200, and a storage device 300 are arranged on a package substrate 400, various operations may be performed by the processing unit 100, utilizing the memory device 200 and the storage device 300. For example, an operation related to an artificial intelligence model may be performed by the processing unit 100, and data generated by the operation may be stored in the memory device 200 or the storage device 300, depending on the type of data.

For example, the processing unit 100 may perform an operation for learning an artificial intelligence model. The processing unit 100 may perform a forward operation to train the artificial intelligence model in the forward direction and generate parameter data, such as weights and biases, that are part of the artificial intelligence model. The processing unit 100 may also perform a backward operation to train the artificial intelligence model in the reverse direction and generate the parameter data.

The processing unit 100 may store various parameter data generated according to the training operation in the memory device 200.

The processing unit 100 may generate checkpoint data based on the generated parameter data. The checkpoint data may include at least a portion of the parameter data, and may also include data regarding momentum or deviation related to the parameter data.

The processing unit 100 may perform an optimization operation to generate checkpoint data at a preset time. For example, the processing unit 100 may perform forward and backward operations, and then perform an optimization operation using the parameter data generated through the operations. In some cases, the processing unit 100 may perform the forward and backward operations multiple times before performing the optimization operation.

The processing unit 100 may store the checkpoint data generated through the optimization operation in the storage device 300. The processing unit 100 may perform an operation for generating and storing checkpoint data based on an internally generated command or a command received from an external host device. The processing unit 100 may generate checkpoint data using parameter data stored in the memory device 200 and store the checkpoint data in the storage device 300 using communication pathways between the memory device 200 and the storage device 300.

Since checkpoint data based on periodically performed optimization operations is directly transferred from the memory device 200 and stored in the storage device 300, it is possible to reduce the time required for generating and storing the checkpoint data. By minimizing the time that training operations are paused for processing checkpoint data, the efficiency of operations for learning artificial intelligence models is improved.

The memory device 200 and the storage device 300 may include various circuits for controlling the movement and storage of checkpoint data.

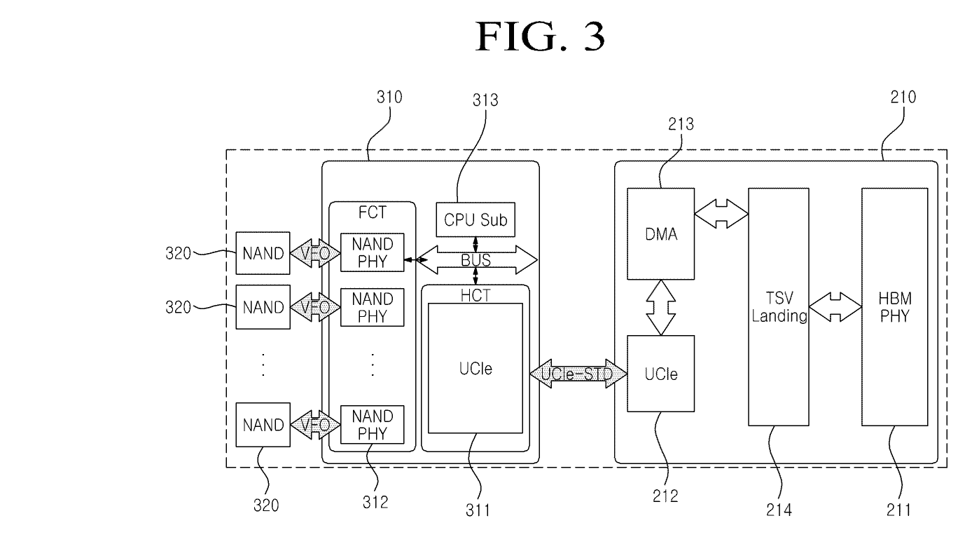

FIG. 3 illustrates an example of a schematic configuration of a memory device and a storage device according to embodiments of the present disclosure.

Referring to FIG. 3, a base die 210 of a memory device 200 of FIG. 2 may include a first interface circuit 211, a first chip-to-chip interface circuit 212, a data movement control circuit 213, and a through-electrode region. If the memory device 200 is a high-bandwidth memory (HBM), the first interface circuit 211 may include an HBM physical layer. The memory device 200 may communicate with a processing unit 100 of FIG. 2 through the first interface circuit 211.

The first interface circuit 211 may be electrically connected to a through-electrode disposed in the through-electrode region 214. A signal received through the first interface circuit 211 may be transmitted to a core die 220 of FIG. 2 through the through-electrode. Data stored in the core die 220 may be provided to the first interface circuit 211 through the through-electrodes.

The first chip-to-chip interface circuit 212 may, for example, support a UCIe communication protocol. The memory device 200 may communicate with a storage device 300 of FIG. 2 through the first chip-to-chip interface circuit 212.

The data movement control circuit 213 may be, for example, a direct memory access (DMA) module. The data movement control circuit 213 may access a through-electrode located in the through-electrode region 214. The data movement control circuit 213 may access data stored in a core die 220 through a through-electrode, and may transmit the data stored in the core die 220 to the storage device 300 through the first chip-to-chip interface circuit 212.

The data movement control circuit 213 may transmit data stored in the core die 220 to the storage device 300 based on a command transmitted by the processing unit 100. The data movement control circuit 213 may control data movement based on a command generated by the processing unit 100 or a command transmitted by the host device and received by the processing unit 100.

A controller 310 of the storage device 300 may include, for example, a second chip-to-chip interface circuit 311, a second interface circuit 312, and a control circuit 313.

The second chip-to-chip interface circuit 311 may support the UCIe communication protocol. The memory device 200 and the storage device 300 may communicate with each other through the second chip-to-chip interface circuit 311 and the first chip-to-chip interface circuit 212.

The second interface circuit 312 may communicate with a memory 320. If the memory 320 is NAND flash memory, the second interface circuit 312 may include a NAND physical layer. The second interface circuit 312 may communicate with the second chip-to-chip interface circuit 311 and the control circuit 313 through a bus. Signals and data received through the second chip-to-chip interface circuit 311 may be transmitted to the memory 320 through the second interface circuit 312. The control circuit 313 may control the overall operation of the controller 310.

The base die 210 of the memory device 200 and the controller 310 of the storage device 300 each include an interface circuit that communicates with the processing unit 100 and the memory 320, and may include a chip-to-chip interface circuit distinct from the interface circuit. Communication between the memory device 200 and the storage device 300 may be performed through the chip-to-chip interface circuits.

According to a command received from the processing unit 100 or a command received from the outside by the processing unit 100, at least a portion of the data stored in the memory device 200 may be moved to the storage device 300 under the control of the data movement control circuit 213. Data periodically stored during the process of performing training operations for an artificial intelligence model, such as checkpoint data, may be moved from the memory device 200 to the storage device 300 and stored, thereby enabling efficient generation and storage of checkpoint data.

In some cases, the controller 310 of the storage device 300 or the base die 210 of the memory device 200 may include an operation circuit. The operation circuit may perform an optimization operation based on parameter data generated by the training operations performed by the processing unit 100 and stored in the memory device 200. The operation circuit may generate checkpoint data through the optimization operation. Since the generation of checkpoint data is performed by the base die 210 of the memory device 200 or the controller 310 of the storage device 300, it is possible to further reduce the amount of data transmitted and received between the memory device 200 and the processing unit 100.

The processing unit 100 may efficiently perform an operation of storing checkpoint data by moving and storing the checkpoint data from the memory device 200 to the storage device 300. In addition, the processing unit 100 may periodically store checkpoint data and perform an operation of restoring parameter data according to training operations using the checkpoint data.

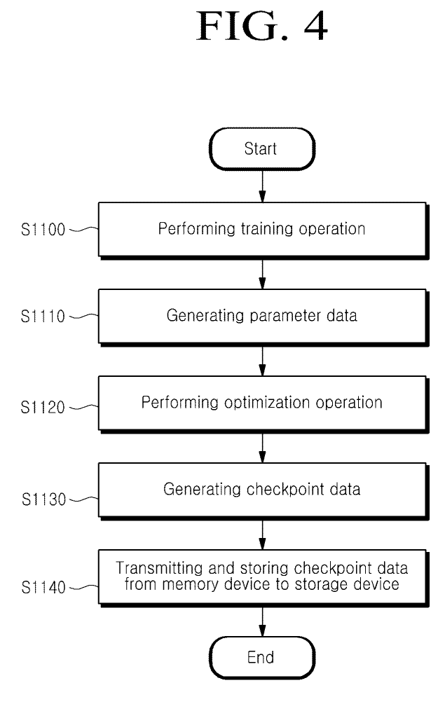

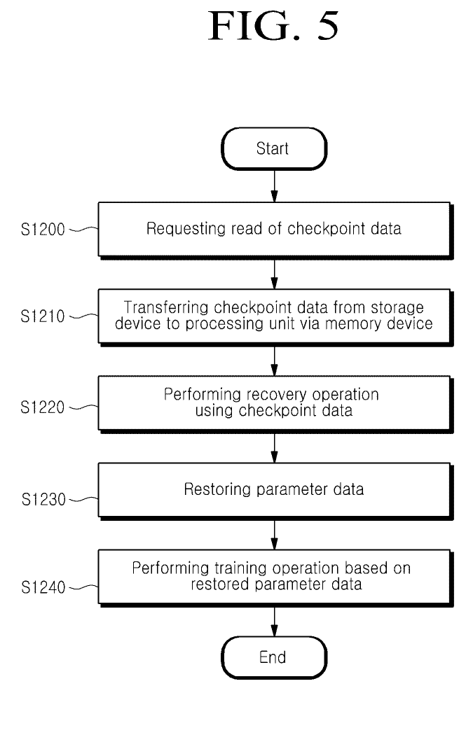

FIGS. 4 and 5 illustrate examples of a method of operating a computing system to perform operations related to an artificial intelligence model according to embodiments of the present disclosure.

Referring to FIG. 4, a processing unit 100 may perform a training operation for learning an artificial intelligence model (S1100). The processing unit 100 may perform forward and backward operations and generate parameter data (S1110).

If the processing unit 100 generates the parameter data, the processing unit may perform an optimization operation using the parameter data at regular intervals (S1120).

The processing unit 100 may perform an optimization operation using, for example, the parameter data generated in the (N-1)-th training operation and the parameter data generated in the N-th training operation. Furthermore, the processing unit 100 may also perform the optimization operation by further using checkpoint data generated in the (N-1)-th optimization operation. The processing unit 100 may generate checkpoint data through the N-th optimization operation (S1130).

When checkpoint data is generated through optimization operations, the processing unit 100 may store the checkpoint data in a storage device 300 (S1140).

The checkpoint data generated by the processing unit 100 through the optimization operations may be stored in a memory device 200. The processing unit 100 may output a command to move at least a portion of the checkpoint data stored in the memory device 200 to the storage device 300. The command may be output by the processing unit 100, or received from a host device located externally and output by the processing unit 100.

When the memory device 200 receives a command transmitted by the processing unit 100, at least a portion of the checkpoint data stored in the memory device 200 may be moved to the storage device 300 by a data movement control circuit 213 included in the memory device 200. The checkpoint data may be transmitted through a chip-to-chip interface circuit included in each of the memory device 200 and the storage device 300, and the checkpoint data may be transmitted to and stored in the storage device 300.

The processing unit 100 may perform a new training operation upon completion of storing checkpoint data. For example, the processing unit 100 may perform an (N+1)-th training operation.

The processing unit 100 may utilize at least a portion of the parameter data generated from an N-th training operation or the checkpoint data generated from an N-th optimization operation to perform the (N+1)-th training operation. The processing unit 100 may perform the (N+1)-th training operation using data stored in the memory device 200, and thereafter perform the (N+1)-th optimization operation, thereby repeatedly performing the operations as described above.

If an error occurs during the training operation, the processing unit 100 may perform a recovery operation using previously stored checkpoint data.

For example, referring to FIG. 5, the processing unit 100 may transmit a read request for checkpoint data to the memory device 200 (S1200). When the processing unit 100 generates a read request for the checkpoint data, checkpoint data stored in the storage device 300 may be transferred to the processing unit 100 via the memory device 200 (S1210).

The processing unit 100 may perform a recovery operation using the checkpoint data (S1220). The processing unit 100 may restore parameter data through the recovery operation (S1230). For example, the processing unit 100 may restore parameter data generated for an (N-1)-th training operation using checkpoint data generated through an (N-1)-th optimization operation.

The processing unit 100 may perform a training operation using the restored parameter data (S1240).

The processing unit 100 may perform a training operation and store the generated checkpoint data in the storage device 300 via the memory device 200, and may receive the checkpoint data from the storage device 300 via the memory device 200, so that even if an error occurs during the training operation, the training operations can continue and be performed again through a recovery operation using the checkpoint data.

By moving the checkpoint data through direct communication between the memory device 200 and the storage device 300, it is possible to prevent or reduce performance degradation due to traditional storage and management of the checkpoint data, and the efficiency of the training operation by the processing unit 100 is enhanced in disclosed embodiments.

A communication path may be provided between the memory device 200 and the storage device 300 through a package substrate 400 in a state in which the memory device 200 is disposed on an interposer 500 together with the processing unit 100, as in the example described above with reference to FIG. 2.

Alternatively, the packaging structure between the processing unit 100, the memory device 200, and the storage device 300 may be implemented in various ways while maintaining direct communication structures between the memory device 200 and the storage device 300.

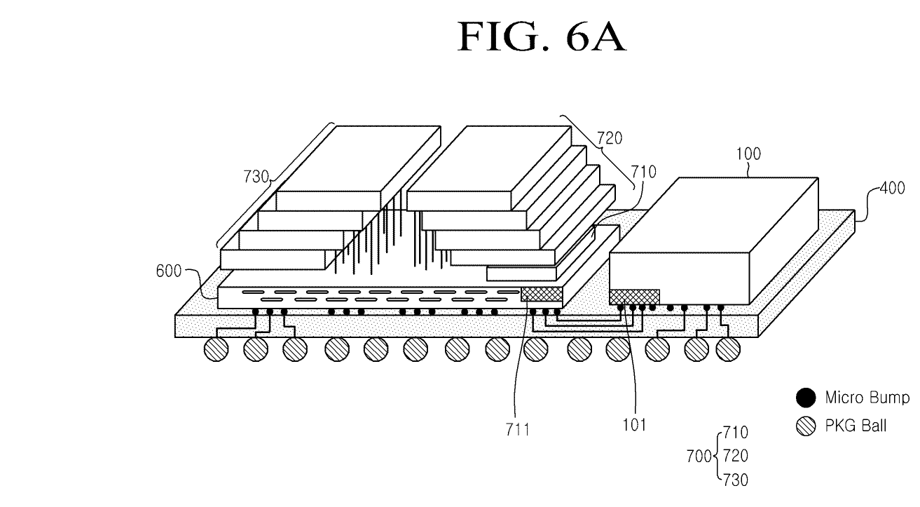

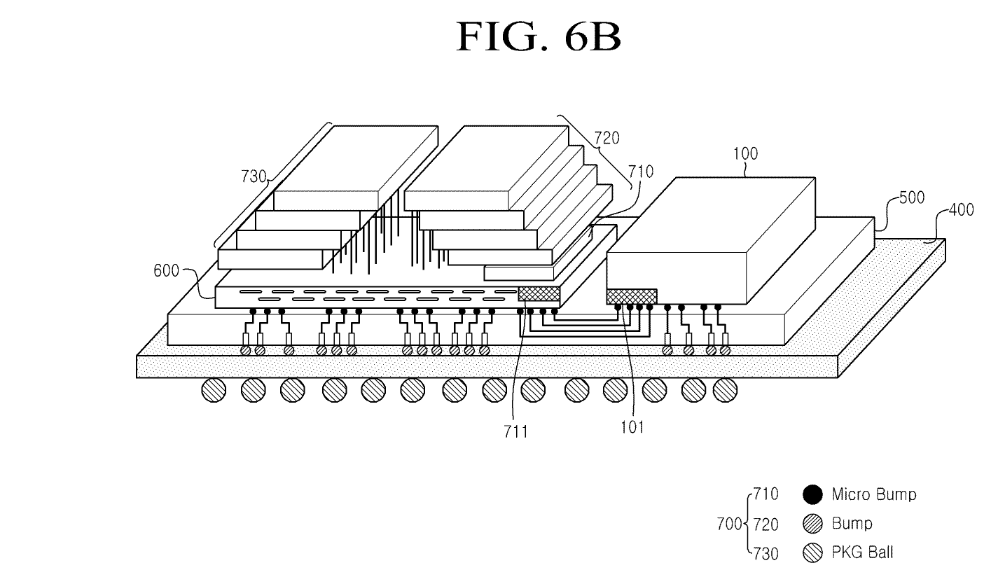

FIGS. 6A, 6B, 7, 8A, and 8B illustrate other examples of specific structures of computing systems according to embodiments of the present disclosure.

Referring to FIG. 6A, a processing unit 100 may be disposed on a package substrate 400. The processing unit 100 may include a processing interface circuit 101.

An integrated memory device 700 may be disposed on the package substrate 400. The integrated memory device 700 may include, for example, an integrated controller 710, a first integrated memory 720, and a second integrated memory 730.

The integrated memory device 700 may be disposed on, for example, a redistribution layer 600. The redistribution layer 600 may be disposed on the package substrate 400. Communication between the processing unit 100 and the redistribution layer 600 may be achieved via a communication path provided by the package substrate 400. The redistribution layer 600 may, in some cases, be referred to as a sub-package substrate. In some cases, an integrated memory device 700 includes the redistribution layer 600.

The integrated controller 710 may include, for example, an integrated interface circuit 711. At least a portion of the integrated interface circuit 711 may be located in the redistribution layer 600. The integrated interface circuit 711 may, for example, support a UCIe communication protocol, but embodiments are not limited thereto.

The integrated controller 710 may communicate with the processing unit 100 via the integrated interface circuit 711. The package substrate 400 may provide a communication path between the integrated controller 710 and the processing unit 100.

The integrated controller 710 may control the first integrated memory 720 and the second integrated memory 730. The first integrated memory 720 and the second integrated memory 730 may be of the same type of memory or of different types of memory. For example, the first integrated memory 720 may be DRAM, and the second integrated memory 730 may be NAND flash, but the present disclosure is not limited thereto.

The first integrated memory 720 and the second integrated memory 730 may be connected to the redistribution layer 600, for example, via a vertical connection wiring. A communication path between the first integrated memory 720, the second integrated memory 730, and the integrated controller 710 may be provided via the redistribution layer 600. In addition, in some cases, a communication path between the first integrated memory 720 and the second integrated memory 730 may be provided through the redistribution layer 600 without the vertical connection wiring. The first integrated memory 720 and the second integrated memory 730 are communicated with each other directly through the redistribution layer 600.

The integrated controller 710 may store data in the first integrated memory 720 according to a command received from the processing unit 100. For example, parameter data generated by a training operation performed by the processing unit 100 may be stored in the first integrated memory 720. In addition, checkpoint data generated by an optimization operation performed using the parameter data after a training operation is performed may be stored in the first integrated memory 720.

The checkpoint data stored in the first integrated memory 720 may be moved from the first integrated memory 720 to the second integrated memory 730 according to a command transmitted by the processing unit 100. If checkpoint data is moved from the first integrated memory 720 to the second integrated memory 730, then the first integrated memory 720 may be used to store data used in training operations performed by the processing unit 100 and to store data generated by the training operations.

In this way, the first integrated memory 720 for storing data generated according to operations performed by the processing unit 100 and a second integrated memory 730 for backing up at least a portion of that data can be provided in a single package form, thereby providing an integrated memory device 700 capable of improving the efficiency of operations performed by the processing unit 100.

In some cases, the processing unit 100 and the integrated memory device 700 may be directly disposed on the package substrate 400 to communicate with each other. Alternatively, an additional layer may be disposed on the package substrate 400 to facilitate wiring connection.

As an example, referring to FIG. 6B, a processing unit 100 and an integrated memory device 700 may be disposed on a package substrate 400. The structure and operation method of the processing unit 100 and the integrated memory device 700 may be the same as that described above with reference to FIG. 6A.

An interposer 500 may be disposed on the package substrate 400. The processing unit 100 and the integrated memory device 700 may be disposed on the interposer 500. A communication path between the processing unit 100 and the integrated memory device 700 may be provided by the interposer 500. The processing unit 100 and package balls placed on the lower surface of the package substrate 400 may be electrically connected through the interposer 500. The integrated memory device 700 and the package balls placed on the lower surface of the package substrate 400 may be electrically connected through the interposer 500. By arranging the interposer 500 between the processing unit 100 and the integrated memory device 700, a communication path may be provided and an electrical connection structure with package balls can also be easily implemented.

In this way, the processing unit 100 and the integrated memory device 700 may be disposed on the interposer 500. In some cases, different types of memories included in the integrated memory device 700 may be arranged separately.

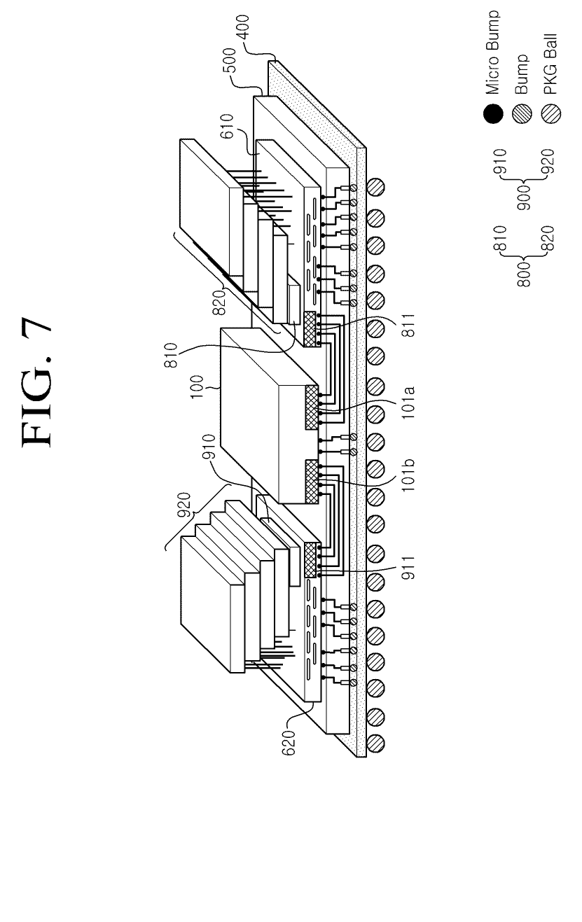

For example, referring to FIG. 7, an interposer 500 may be disposed on a package substrate 400. A processing unit 100 may be disposed on the interposer 500. The processing unit 100 may include a first processing interface circuit 101a and a second processing interface circuit 101b. The first processing interface circuit 101a and the second processing interface circuit 101b may support a UCIe communication protocol, but embodiments are not limited thereto.

A first memory device 800 and a second memory device 900 may be disposed on the interposer 500.

The first memory device 800 may include, for example, a first memory controller 810 and a first memory 820. The first memory device 800 may be disposed on a first redistribution layer 610. In some cases, the first memory device 800 may include the first redistribution layer 610.

The first memory controller 810 may communicate with the processing unit 100 and control the first memory 820.

The first memory controller 810 may include a first memory interface circuit 811. The first memory interface circuit 811 may support, but is not limited to, the UCIe communication protocol. In some cases, at least a portion of the first memory interface circuit 811 may be located on or in the first redistribution layer 610.

At least one first memory 820 may be disposed on the first memory controller 810. The first memory 820 may be, for example, a volatile memory such as DRAM. The first memory 820 may be electrically connected to the first redistribution layer 610 via a vertical connection wiring.

The first redistribution layer 610 may provide a communication path between the first memory controller 810 and the first memory 820. The first memory controller 810 may communicate with the first memory 820 through the first redistribution layer 610. The first memory controller 810 may communicate with the processing unit 100 through the interposer 500.

The second memory device 900 may include, for example, a second memory controller 910 and a second memory 920. The second memory device 900 may be disposed on a second redistribution layer 620. In some cases, the second memory device 900 may include the second redistribution layer 620.

The second memory controller 910 may communicate with the processing unit 100 and control the second memory 920. The second memory controller 910 may include, for example, a second memory interface circuit 911. The second memory interface circuit 911 may support, but is not limited to, the UCIe communication protocol. In some cases, at least a portion of the second memory interface circuit 911 may be located on or in the second redistribution layer 620.

A communication path between the processing unit 100 and the second memory device 900 may be provided by the interposer 500.

The second memory controller 910 may be disposed on the second redistribution layer 620. At least one second memory 920 may be disposed on the second memory controller 910. The second memory 920 may be electrically connected to the second redistribution layer 620 via a vertical connection wiring. The second redistribution layer 620 may provide a communication path between the second memory controller 910 and the second memory 920.

The processing unit 100 may store parameter data, generated by a training operation of the processing unit 100, in the first memory device 800. The processing unit 100 may generate checkpoint data at preset intervals using the parameter data. If the checkpoint data generation is complete, then the processing unit 100 may store the checkpoint data in the second memory device 900.

The checkpoint data may be stored in the first memory device 800 upon generation, and then may be moved from the first memory device 800 and stored in the second memory device 900 after completing the optimization operation for generating the checkpoint data. The checkpoint data may be moved or migrated to the second memory device 900 via the processing unit 100. The first memory device 800 may be used to store data used or generated for a training operation by the processing unit 100.

In this way, the arrangement structure of a device that stores data according to operations for learning the artificial intelligence model by the processing unit 100 may be implemented in various ways. In addition, in some cases, the processing unit 100 may be provided by being packaged with a storage device 300, and a memory device 200 may be provided separately and connected to the processing unit 100 or the storage device 300.

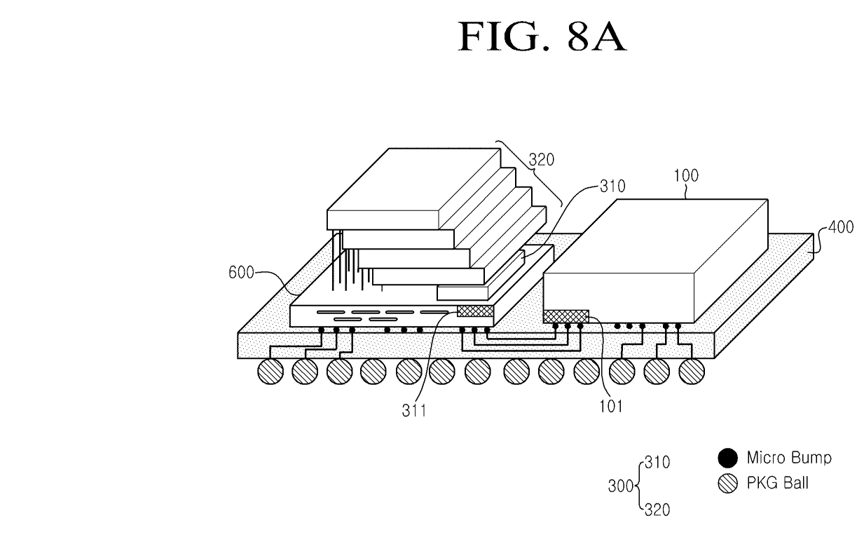

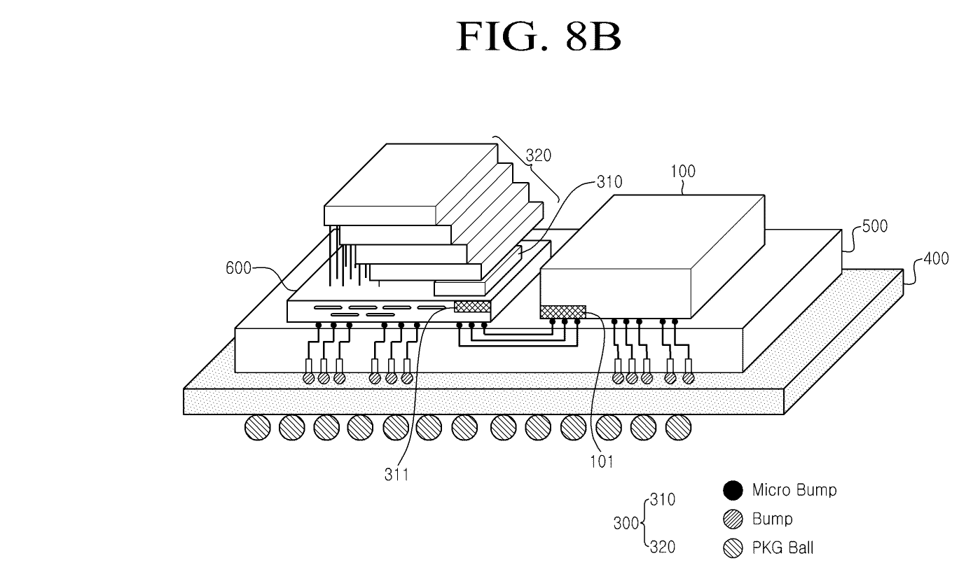

As an example, referring to FIG. 8A, a processing unit 100 and a storage device 300 may be disposed on a package substrate 400. Alternatively, as illustrated in FIG. 8B, an interposer 500 may be disposed on a package substrate 400, and a processing unit 100 and a storage device 300 may be disposed on the interposer 500.

Referring to FIGS. 8A and 8B, the processing unit 100 may include a processing interface circuit 101. The storage device 300 may be disposed on a redistribution layer 600. The storage device 300 may include a controller 310 and a memory 320. The controller 310 may include a second chip-to-chip interface circuit 311. In some cases, at least a portion of the second chip-to-chip interface circuit 311 may be located on or in the redistribution layer 600.

The controller 310 may communicate with the processing interface circuit 101 of the processing unit 100 through the second chip-to-chip interface circuit 311. A communication path between the second chip-to-chip interface circuit 311 and the processing interface circuit 101 may be provided by the package substrate 400 (FIG. 8A) or the interposer 500 (FIG. 8B).

A memory device 200 used by the processing unit 100 for computations such as learning an artificial intelligence model, although not illustrated in FIGS. 8A or FIG. 8B, may be disposed on a substrate separate from the package substrate 400 illustrated in FIGS. 8A and FIG. 8B.

The memory device 200 may communicate with the processing unit 100 via, for example, a communication path provided by the package substrate 400 and a substrate on which the memory device 200 is disposed. Alternatively, the memory device 200 may communicate with the storage device 300 via a communication path provided by the package substrate 400 and a substrate on which the memory device 200 is disposed. In some cases, the memory device 200 may communicate with both of the processing unit 100 and the storage device 300.

The processing unit 100 may store data used in a training operation for learning an artificial intelligence model, or data generated by the training operation, using the memory device 200 located apart from the package substrate 400. The processing unit 100 may perform an optimization operation based on parameter data generated according to the training operation and generate checkpoint data.

The processing unit 100 may directly store the generated checkpoint data in the storage device 300, or, after storing the generated checkpoint data in the memory device 200, may move the checkpoint data stored in the memory device 200 to the storage device 300 after the checkpoint data generation is complete.

According to embodiments of the present disclosure described above, it is possible to provide a computing system including heterogeneous data storage devices that store data according to operations performed by the processing unit 100.

The processing unit 100 may store parameter data, according to the training operations for learning an artificial intelligence model, in the memory device 200 and may move and store checkpoint data, generated at preset times based on the parameter data from the memory device 200, to the storage device 300.

Therefore, it is possible to reduce the delay caused by generating and storing checkpoint data periodically performed during learning of an artificial intelligence model, thereby improving the efficiency of the operation by the processing unit 100. In addition, it is possible to provide various structures in which the processing unit 100 and at least one of the memory device 200 or the storage device 300 are packaged, thereby implementing computing systems with various efficient structures to be used for learning or inference of an artificial intelligence model.

Although various embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope of the invention as defined in the following claims.

What is claimed is:

1. A computing system comprising:
a processing unit;
at least one memory device, including a first interface circuit configured to communicate with the processing unit and a first chip-to-chip interface circuit, and configured to store parameter data generated by an operation performed by the processing unit; and
at least one storage device, including a second chip-to-chip interface circuit configured to communicate with the at least one memory device, and configured to receive and store at least a portion of checkpoint data generated at a preset time based on the parameter data from the at least one memory device.

2. The computing system of claim 1, further comprising an interposer,
wherein the processing unit and the at least one memory device are disposed in the interposer, and
wherein a path for communication between the processing unit and the at least one memory device is disposed in the interposer.

3. The computing system of claim 2, further comprising a package substrate,
wherein the interposer and the at least one storage device are disposed on the package substrate, and
wherein a path for communication between the at least one memory device and the at least one storage device is disposed in the package substrate.

4. The computing system of claim 1, further comprising a sub-package substrate,
wherein the at least one memory device and the at least one storage device are disposed on the sub-package substrate, and
wherein a path for communication between the at least one memory device and the at least one storage device is disposed in the sub-package substrate.

5. The computing system of claim 1, wherein the at least one memory device includes:
a base die including the first interface circuit, the first chip-to-chip interface circuit, and a data movement control circuit that controls transmission of the checkpoint data; and
at least one core die disposed on the base die and storing at least a portion of the parameter data or the checkpoint data.

6. The computing system of claim 5, wherein the data movement control circuit is configured to access the at least one core die according to a command transmitted by the processing unit, and to transmit the checkpoint data to the at least one storage device.

7. The computing system of claim 5, wherein the base die includes a path for communication between the first interface circuit and the at least one core die includes a plurality of through-electrodes, which are accessed by the data movement control circuit.

8. The computing system of claim 5, wherein the base die includes an operation circuit configured to generate the checkpoint data using the parameter data.

9. The computing system of claim 1, wherein the at least one storage device include:
at least one memory; and
a controller configured to control the at least one memory, to include the second chip-to-chip interface circuit and a second interface circuit, and to communicate with the at least one memory.

10. The computing system of claim 9, further comprising a redistribution layer,
wherein the at least one storage device is disposed in the redistribution layer and
wherein a path for communication between the at least one memory and the controller is disposed in the redistribution layer.

11. The computing system of claim 10, wherein the controller is disposed on the redistribution layer, the at least one memory is disposed on the controller, and the at least one memory is electrically connected to the redistribution layer through at least one vertical connection wiring.

12. The computing system of claim 1, wherein the processing unit is configured to perform an optimization operation using the generated parameter data to generate the checkpoint data, and to transmit at least a portion of the parameter data or the checkpoint data to the at least one storage device through the at least one memory device.

13. The computing system of claim 1, wherein the processing unit is configured to receive the checkpoint data stored in the at least one storage device through the at least one memory device, and to recover the parameter data using the checkpoint data.

14. A memory package comprising:
a package substrate;
at least one first memory device disposed on the package substrate, including a base die and at least one first memory disposed on the base die, the base die including a first interface circuit configured to communicate with an externally located processing unit and a first chip-to-chip interface circuit; and
at least one second memory device disposed on the package substrate, including at least one second memory and a controller controlling the at least one second memory, the controller including a second interface circuit configured to communicate with the at least one second memory and a second chip-to-chip interface circuit configured to communicate with the at least one first memory device.

15. The memory package of claim 14, wherein a path for communication between the first chip-to-chip interface circuit and the second chip-to-chip interface circuit is disposed in the package substrate.

16. The memory package of claim 14, wherein the at least one first memory device further includes a data movement control circuit configured to transmit data stored in the at least one first memory to the at least one second memory device.

17. The memory package of claim 16, wherein the data movement control circuit is configured to transmit at least a portion of the data stored in the at least one first memory to the controller through the first chip-to-chip interface circuit in accordance with a command transmitted by the processing unit.

18. The memory package of claim 16, wherein the controller is configured to transmit data stored in the at least one second memory to the processing unit via the at least one first memory device in accordance with a command transmitted by the processing unit.

19. A processor package comprising:
a package substrate;
a processing unit on the package substrate; and
at least one memory device including an interface circuit configured to communicate with the processing unit and a chip-to-chip interface circuit, and configured to store parameter data generated by an operation performed by the processing unit, and configured to transmit at least a portion of checkpoint data generated based on the parameter data to an outside through the chip-to-chip interface circuit.

20. The processor package of claim 19, wherein the at least one memory device includes a data movement control circuit that is configured to transmit at least a portion of the checkpoint data to the outside through the chip-to-chip interface circuit in accordance with a command transmitted by the processing unit.
